(19) United States
(12) Patent Application Publication
(10) Pub. No.: US 2025/0164592 A1
(43) Pub. Date: May 22, 2025

(54) SPECTRUM ANALYSIS APPARATUS, SPECTRUM ANALYSIS METHOD, AND STORAGE MEDIUM

(71) Applicant: Canon Medical Systems Corporation, Otawara-shi (JP)

(72) Inventor: Hidenori TAKESHIMA, Tokyo (JP)

(73) Assignee: Canon Medical Systems Corporation, Otawara-shi (JP)

(21) Appl. No.: 18/938,430

(22) Filed: Nov. 6, 2024

(30) Foreign Application Priority Data
Nov. 17, 2023 (JP) 2023-196099

(51) Int. Cl. G01R 33/46; G01N 24/08; G01R 33/485

(52) U.S. Cl. CPC G01R 33/4625; G01N 24/08; G01R 33/4616; G01R 33/485

(57) ABSTRACT

According to one embodiment, a spectrum analysis apparatus includes processing circuitry. The processing circuitry obtains an acquired spectrum of an MRS pulse sequence with respect to a material. The processing circuitry inputs a basis set including a plurality of spectrum bases respectively corresponding to a plurality of materials. The basis set includes a plurality of basis fragments obtained by dividing, based on a predetermined criterion, a basis spectrum relating to a material of interest which is some or all of the materials. The processing circuitry performs a regression calculation which applies the basis set to the acquired spectrum and outputs a result of spectrum analysis based on the regression calculation.

### CROSS-REFERENCE TO RELATED APPLICATION(S)

This application is based upon and claims the benefit of priority from Japanese Patent Application No. 2023-196099, filed Nov. 17, 2023, the entire contents of which are incorporated herein by reference.

### FIELD

Embodiments described herein relate generally to a spectrum analysis apparatus, a spectrum analysis method, a storage medium.

### BACKGROUND

Magnetic resonance spectroscopy (MRS) can analyze types of metabolites in vivo from acquired spectrum. MRS applies an RF pulse that excites all bandwidths, thereby causing a weak signal component to be buried in a dominant signal component. Editing MRS is known as a technique of breaking down various signal components included in a spectrum. As one of the pulse sequences used in editing MRS, a MEGA-PRESS method is known.

Such a MEGA-PRESS method acquires a signal through PRESS with an application of a frequency selective pulse called a “MEGA pulse” and acquires another signal PRESS through PRSS without an application of such a frequency selective pulse, and obtains a subtraction spectrum based on these signal datasets, thereby being able to detect a weak signal component based on a difference between spectra with and without an application of a frequency selective pulse; however, there is a tendency for a signal-to-noise ratio (SNR) to be low.

One example of concentration estimation by the MEGA-PRESS method is a spectrum analysis method by a regression calculation using basis spectra. There is a tendency for this spectrum analysis method to be decreased in analysis accuracy in a case where prepared basis spectra do not match basis spectra expected for acquired datasets.

### BRIEF DESCRIPTION OF THE DRAWINGS

FIG. 1 is a diagram showing a configuration example of a magnetic resonance signal acquisition apparatus according to an embodiment.

FIG. 2 is a diagram showing an example of a MEGA-PRESS pulse sequence.

FIG. 3 is a diagram showing an example of a first spectrum by a PRESS unit, a second spectrum by a MEGA-PRESS unit, and a subtraction spectrum in these spectra.

FIG. 4 is a diagram showing an example of a basis set.

FIG. 5 is a diagram showing examples of a GABA spectrum and a glucose (Glu) spectrum.

FIG. 6 is a diagram showing an example of division processing of a spectral basis using a second division criterion (the number of edition frequency bands is one).

FIG. 7 is a diagram showing an example of division processing of a spectral basis using a second division criterion (the number of edition frequency bands is two).

FIG. 8 is a diagram showing an example of division processing of a spectral basis using a third division criterion.

FIG. 9 is a diagram showing an example of a processing procedure of spectrum analysis processing by a spectrum analysis apparatus.

FIG. 10 is a diagram showing an example of a result of spectrum analysis in a case of a spectral basis being not divided, and a result of spectrum analysis in a case of the spectral basis being divided.

FIG. 11 is a diagram showing an example of a processing procedure of determination processing of a basis set by the spectrum analysis apparatus.

### DETAILED DESCRIPTION

A spectrum analysis apparatus according to an embodiment includes an obtainment unit, an input unit, and a calculation unit. The obtainment unit obtains an acquired spectrum of an MRS pulse sequence with respect to a subject. The input unit is a unit configured to input a basis set including a plurality of spectrum bases respectively corresponding to a plurality of materials. The basis set includes a plurality of basis fragments obtained by dividing, based on a predetermined criterion, a spectral basis relating to a material of interest which is all or some of the aforementioned materials. The calculation unit performs a regression calculation, which applies the basis set to the acquired spectrum, and outputs a result of spectrum analysis based on the regression calculation.

Hereinafter, a spectrum analysis apparatus, a spectrum analysis method, and a storage medium according to a present embodiment will be described in detail with reference to the drawings.

The spectrum analysis apparatus according to the present embodiment is a computer configured to analyze a spectrum by MR spectroscopy. The spectrum analysis apparatus in the following is a computer included in a magnetic resonance signal acquisition apparatus but may be a computer which is separate from the magnetic resonance signal acquisition apparatus.

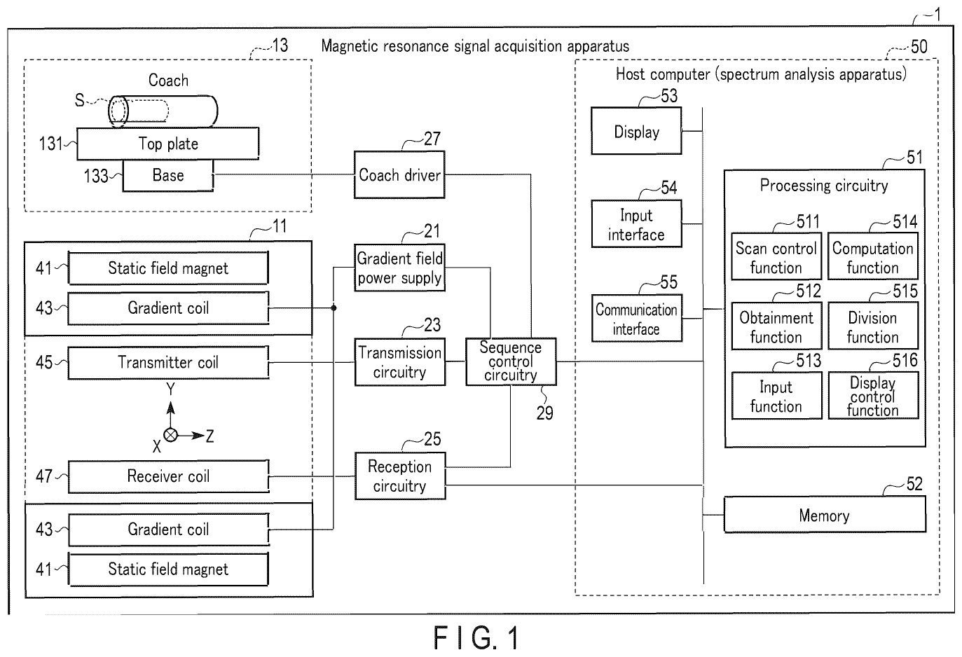

FIG. 1 is a diagram showing a configuration example of the magnetic resonance signal acquisition apparatus 1 according to the present embodiment. As shown in FIG. 1, a magnetic resonance signal acquisition apparatus 1 includes a gantry 11, a couch 13, a gradient field power supply 21, transmission circuitry 23, reception circuitry 25, a couch driver 27, sequence control circuitry 29, and a host computer (spectrum analysis apparatus) 50.

The gantry 11 includes a static magnetic field magnet 41 and a gradient coil 43. The static magnetic field magnet 41 and the gradient coil 43 are accommodated in the housing of the gantry 11. A bore with a hollow shape is formed in the housing of the gantry 11. A transmitter coil 45 and a receiver coil 47 are disposed in the bore of the gantry 11.

The static magnetic field magnet 41 has a hollow approximately cylindrical shape and generates a static magnetic field inside the approximate cylinder. The static magnetic field magnet 41 uses, for example, a permanent magnet, a superconducting magnet, a normal conducting magnet, etc. The central axis of the static magnetic field magnet 41 is defined as a Z axis; an axis vertically perpendicular to the Z axis is defined as a Y axis; and an axis horizontally perpendicular to the Z axis is defined as an X axis. The X-axis, the Y-axis and the Z-axis constitute an orthogonal three-dimensional coordinate system.

The gradient coil 43 is a coil unit attached to the inside of the static magnetic field magnet 41 and formed in a hollow, approximately cylindrical shape. The gradient coil 43 generates a gradient field upon receiving a current supplied from the gradient field power supply 21. Specifically, the gradient coil 43 includes three coils corresponding respectively to the X, Y, and Z axes which are perpendicular to each other. The three coils generate gradient fields in which the magnetic field magnitude changes along the X, Y, and Z axes. The gradient magnetic fields along the X, Y, and Z axes are combined to generate a slice selective gradient field Gs, a phase encoding field Gp, and a frequency encoding gradient field Gr, which are perpendicular to each other, in desired directions. The slice selective gradient field Gs is used to discretionarily determine an imaging slice. The phase encoding gradient field Gp is used to change a phase of magnetic resonance signals (hereinafter “MR signals”) in accordance with a spatial position. The frequency encoding gradient field Gr is used to change a frequency of an MR signal in accordance with a spatial position. In the following description, it is assumed that the gradient direction of the slice selective gradient field Gs aligns with the Z axis, the gradient direction of the phase encoding gradient field Gp aligns with the Y axis, and the gradient direction of the frequency encoding gradient field Gr aligns with the X axis.

The gradient field power supply 21 supplies a current to the gradient coil 43 in accordance with a sequence control signal from the sequence control circuitry 29. Through the supply of the current to the gradient coil 43, the gradient field power supply 21 makes the gradient coil 43 generate gradient fields along the X-axis, the Y-axis, and the Z-axis. These gradient fields are superimposed on the static magnetic field formed by the static magnetic field magnet 41 and are applied to the subject S.

The transmitter coil 45 is arranged inside the gradient coil 43 and generates a high-frequency pulse (hereinafter referred to as an RF pulse) upon receipt of a current supplied from the transmission circuitry 23.

The transmission circuitry 23 supplies a current to the transmitter coil 45 in order to apply an RF pulse for exciting target protons in the subject S to the subject S via the transmitter coil 45. The RF pulse vibrates at a resonance frequency specific to the target protons, and electrically excites those target protons. An MR signal is generated from the electrically excited target protons and is detected by the receiver coil 47. The transmitter coil 45 is, for example, a whole-body coil (WB coil). The whole-body coil may be used as a transmitter/receiver coil.

The receiver coil 47 receives an MR signal generated from the target protons that are present in the subject S as a result of the effects of the RF pulse. The receiver coil 47 includes a plurality of receiver coil elements capable of receiving MR signals. The received MR signal is supplied to the reception circuitry 25 by wiring or wirelessly. Although not shown in FIG. 1, the receiver coil 47 has a plurality of reception channels arranged in parallel. Each receiver channel includes a receiver coil element that receives MR signals, an amplifier that amplifies the MR signals, etc. An MR signal is output from each reception channel. The total number of the reception channels may be equal to, larger than, or smaller than the total number of the receiver coil elements.

The reception circuitry 25 receives an MR signal generated from the excited target protons via the receiver coil 47. The reception circuitry 25 processes the received MR signal to generate a digital MR signal. The digital MR signal can be expressed by a k-space defined by spatial frequency. Hereinafter, the digital MR signals are referred to as k-space data. k-space data is digital data in which a signal strength value of an MR signal is expressed with a time function. k-space data is supplied to the host computer 50 either by wiring or wirelessly.

The transmitter coil 45 and the receiver coil 47 described above are merely examples. A transmitter/receiver coil which has a transmit function and a receive function may be used instead of the transmitter coil 45 and the receiver coil 47. Alternatively, the transmitter coil 45, the receiver coil 47, and the transmitter/receiver coil may be combined.

The couch 13 is installed adjacent to the gantry 11. The couch 13 includes a top plate 131 and a base 133. The subject S is placed horizontally on the top plate 131. The base 133 supports the top plate 131 slidably along each of the X-axis, the Y-axis, and the Z-axis. The couch driver 27 is accommodated in the base 133. The couch driver 27 moves the top plate 131 under the control of the sequence control circuitry 29. The couch driver 27 may include, for example, any motor such as a servo motor or a stepping motor. The subject S is placed horizontally in the present embodiment; however, the subject S may be placed vertically.

The sequence control circuitry 29 includes, as hardware resources, a processor such as a central processing unit (CPU) or a micro processing unit (MPU), and a type of memory such as read only memory (ROM) and random access memory (RAM). The sequence control circuitry 29 controls the gradient field power supply 21, the transmission circuitry 23, and the reception circuitry 25 synchronously based on reset acquisition conditions, and acquires k-space data relating to the subject S by performing signal acquisition in accordance with the acquisition conditions on the subject S.

The sequence control circuitry 29 according to the present embodiment performs signal acquisition for MR spectroscopy (MRS), which is a type of chemical shift measurement. Chemical shift measurement is a technique of measuring a chemical shift that is a slight difference between resonance frequencies of a target proton, such as a hydrogen atomic nuclei, etc., which is caused by different chemical environments. The MRS includes a single voxel technique in which signal acquisition is performed on a single voxel and a multi-voxel technique in which signal acquisition is performed on multiple voxels, and the present embodiment is applicable to both of these techniques. The multi-voxel method is also referred to as chemical shift imaging (CSI) or MRS imaging (MRSI). The sequence control circuitry 29 performs signal acquisition on the subject S using a pulse sequence (MRS pulse sequence) by MR spectroscopy. Performing an MRS pulse sequence causes generation of an MR signal, such as a free induction decay (FID) signal or a spin echo signal, from a measurement target of the subject S. The reception circuitry 25 receives an observable MR signal, such as an FID signal or a spin echo signal, via the receiver coil 47, and performs signal processing on the received MR signal to acquire k-space data relating to the measurement target.

As shown in FIG. 1, the host computer 50 is a computer having processing circuitry 51, a memory 52, a display 53, an input interface 54, and a communication interface 55. Data communications between the processing circuitry 51, the memory 52, the display 53, the input interface 54, and the communication interface 55 are performed via a bus.

The processing circuitry 51 includes a processor such as a CPU, etc., as hardware resources. The processing circuitry 51 functions as the main unit of the magnetic resonance signal acquisition apparatus 1. For example, the processing circuitry 51 executes various programs to realize a scan control function 511, an obtainment function 512, an input function 513, a calculation function 514, a division function 515, and a display control function 516.

Through realization of the scan control function 511, the processing circuitry 51 performs signal acquisition in accordance with the MRS pulse sequences on the subject S, thereby acquiring k-space data and a spectrum based on the k-space data via the reception circuitry 25.

It is assumed that the MRS according to the present embodiment is editing MRS that adds a frequency selective pulse to a basic sequence of the MRS pulse sequence. In such a case, example items of signal acquisition conditions include a type of basic sequence, a type of frequency selective pulse, a frequency band of a frequency selective pulse (hereinafter, referred to as an “edition frequency band”), a repetition time (TR), an echo time (TE), the number of excitations (NEX), etc. As the pulse sequence, point resolved spectroscopy (PRESS), stimulated echo acquisition mode (STEAM), localization by adiabatic selective refocusing (LASER), semi-LASER, image-selected in vivo spectroscopy (ISIS), and their advanced techniques are used. As the frequency selective pulse, Mescher-Garwood) (MEGA) pulse, band-selective inversion with gradient dephasing (BASING) pulse, SLOtboom-Weng (SLOW) pulse, and their advanced form are used, for example. As a method of utilizing a BASING pulse, a Single-BASING pulse and Double-BASING pulse are known. Types of the basic sequence and frequency selection pulse can be manually set by a user or can be automatically set by an algorithm. The edition frequency band can be manually set by a user or can be automatically set by an algorithm.

Hereinafter, it is assumed that the editing MRS according to the present embodiment is MEGA-PRESS. The MEGA-PRESS performs signal acquisition PRESS with and without an application of a MEGA pulse to obtain a subtraction spectrum between these datasets, thereby extracting a difference signal component resulting from a difference in magnetic environment between these datasets of signal acquisition. Such a signal analysis method is also referred to as a frequency edit.

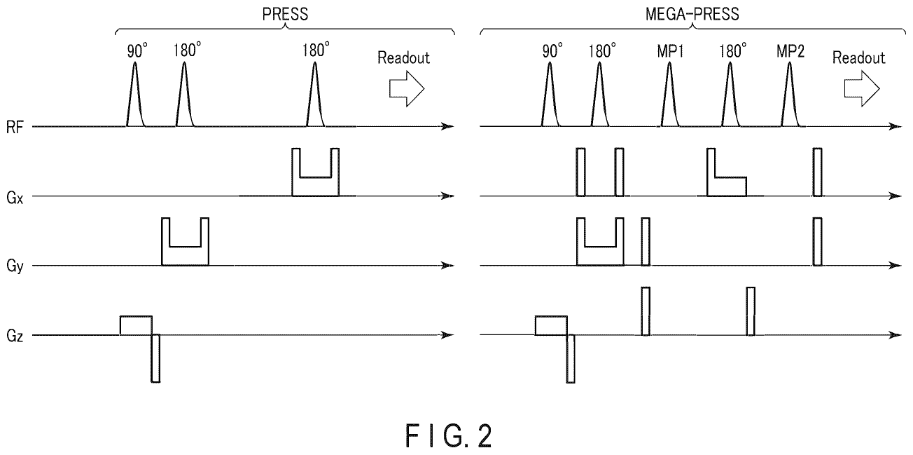

FIG. 2 is a diagram showing an example of a pulse sequence of MEGA-PRESS. FIG. 2 shows an example of a pulse sequence corresponding to one repetition time (TR). A pulse sequence of the MEGA-PRESS includes a pulse sequence portion with an application of a MEGA pulse (PRESS unit) and a pulse sequence portion without an application of a MEGA pulse (MEGA-PRESS unit). The PRESS unit and the MEGA-PRESS unit may be alternatively executed for the number of excitations (NEX), or each of the PRESS unit and the MEGA-PRESS unit may be continuously executed for the number of excitations. The order of the PRESS unit and the MEGA-PRESS unit can be discretionarily set.

As shown in FIG. 2, the PRESS unit generates an MR signal using one 90° excitation pulse and two subsequent 180° inverse pulses. In the description hereinafter, an example where three axes, X-direction, Y-direction, and Z-direction axes are selected in this order will be discussed; however, the description is applicable to the case where these three axes are rotated in arbitrary chosen directions. A slice relating to the Z direction is excited by a 90° pulse and a Gz gradient field pulse multiplexed thereon. A slice relating to the Y direction is excited by a first-time 180° pulse and a Gy gradient field pulse multiplexed thereon. A slice relating to the X direction is excited by a second-time 180° pulse and a Gx gradient field pulse is multiplexed thereon. Thus, a voxel of interest that intersects with an orthogonal three slices is selected and an MR signal is generated from the voxel of interest. The generated MR signal is read by a discretionarily selected read gradient field (Readout), and k-space data corresponding to the MR signal is acquired.

As shown in FIG. 2, in the MEGA-PRESS unit, a MEGA pulse MP1 and a MEGA pulse MP2, which are a type of frequency selective pulse, are applied between three irradiations of RF pulse by the PRESS method. Specifically, a first MEGA pulse MP1 is applied between a first 180° inverse pulse and a second 180° inverse pulse, and a second MEGA pulse MP2 is applied after a second 180° inverse pulse. As the MEGA pulses MP1 and MP2, a 180° pulse is used, for example. The waveforms of MEGA pulse MP1 and MP2 are not limited to a particular shape; however, a Gaussian pulse may be used, for example.

By MEGA pulses MP1 and MP2 being applied, a signal component belonging to an edition frequency band which is a transmit frequency band of the MEGA pulses MP1 and MP2 is suppressed. As with the PRESS unit, the MEGA-PRESS unit also generates an MR signal using one 90° excitation pulse and two subsequent 180° inverse pulses. The generated MR signal is read by a discretionarily selected read gradient field (Readout), and k-space data corresponding to the MR signal is acquired. k-space data acquired by the MEGA-PRESS unit is changed to a signal in which a selective spoiler gradient magnetic field is applied to a signal component belonging to an edition frequency band, as compared to k-space data acquired by the PRESS unit. In FIG. 2, MEGA pulses MP1 and MP2 are applied twice; however, the embodiment is not limited to this example, MP2 pulses may be applied only once or three or more times.

Each of the PRESS unit and the MEGA-press part is repeated for the number of integrations (NEX). The processing circuitry 51 integrates NEX sets of k-space data. Noise can be reduced by integration. The processing circuitry 51 generates a spectrum by performing Fourier Transform on k-space data after each integration operation. In the process of generating a spectrum, various types of correction processing, such as zero-filling processing, phase correction, or a baseline correction, etc., may be performed. A spectrum represents a signal distribution wherein a signal strength is defined on a first axis and a chemical frequency is defined on a second axis orthogonal to the first axis. A spectrum acquired by the PRESS unit (MEGA pulse OFF) will be hereinafter called a “first spectrum”, and a spectrum acquired by the MEGA-PRESS unit (MEGA pulse ON) will be hereinafter called a “second spectrum”.

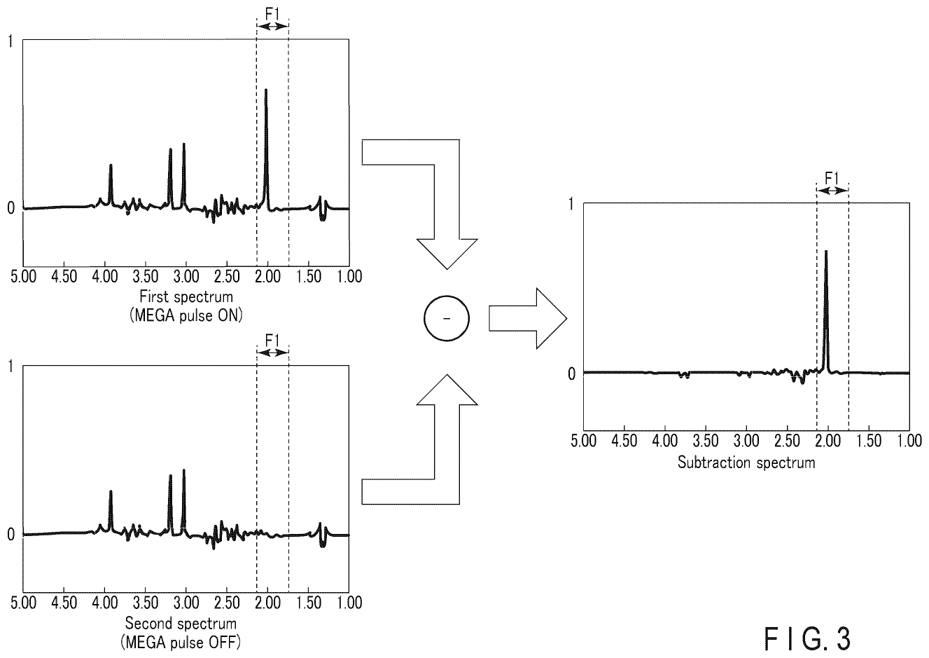

FIG. 3 is a diagram showing an example of a first spectrum by a PRESS unit, a second spectrum by a MEGA-PRESS unit, and a subtraction spectrum in these spectra. The vertical axis of each spectrum represents a signal strength [AU], and the horizontal axis of each spectrum represents a chemical shift frequency [ppm]. Assume that a signal acquisition band of MEGA-PRESS as a whole is, for example, around 1500 to 5000 Hz. Assume that a measurement target of MEGA-PRESS shown in FIG. 3 includes any discretionarily selected metabolite such as GABA, glucose (Glu), 2HG, NAA, GSH, etc.

As shown in FIG. 3, the first spectrum has a strong peak value within a frequency band F1 around 2.00 ppm. Assume that the aforementioned peak value is caused by a metabolite such as GABA, glucose, etc. The example case shown in FIG. 3 assumes the frequency band F1 set to an edition frequency band. A signal component of the edition frequency band F1 is present in the first spectrum because it is acquired by PRESS without an application of a MEGA pulse. A signal component of the edition frequency band F1 is lost in the second spectrum because it is acquired by PRESS (MEGA-PRESS) with an application of a MEGA pulse.

As shown in FIG. 3, for example, through realization of the scan control function 511, the processing circuitry 51 generates a subtraction spectrum by subtracting the second spectrum from the first spectrum. A signal component of the edition frequency band F1 remains in the subtraction spectrum. Due to a difference in magnetic environment resulting from a difference between MEGA pulse-ON and MEGA pulse-OFF, the subtraction spectrum may include a difference signal component in a frequency band other than the edition frequency band F1. The difference signal components include a signal component originating from J-coupling that occurs in a partial structure in which an edition frequency band of a measurement target falls on a resonance frequency. Data of the first spectrum, the second spectrum, and/or the subtraction spectrum is an example of an acquired spectrum.

Through realization of the obtainment function 512, the processing circuitry 51 obtains an acquired spectrum of an MRS pulse sequence, acquired through the scan control function 511, with respect to the subject S. The acquired spectrum means a spectrum obtained by signal acquisition through realization of the scan control function 511. With respect to a spectrum (first spectrum) obtained through an MRS pulse sequence without a frequency selective pulse, a spectrum (second spectrum) obtained through an MRS pulse sequence with a frequency selective pulse, and a subtraction spectrum between the first spectrum and the second spectrum, one of them may be obtained as an acquired spectrum. The processing circuitry 51 may obtain an acquired spectrum from the reception circuitry 25 or an acquired spectrum stored in the memory 42.

Through realization of the input function 513, the processing circuitry 51 inputs a basis set including a plurality of spectrum bases respectively corresponding to a plurality of materials. The “plurality of materials” mean materials targeted for spectrum analysis, out of various materials expected to be included in the subject S. The subject S includes tens, hundreds, or more types of materials; however, of these materials, several types of materials targeted for spectrum analysis are set to the “plurality of materials”. The “material” mainly means a metabolite and therefore will be referred to as a “metabolite” for convenience. A spectral basis is prepared for each of the materials. The spectral basis is data indicative of a standard spectrum waveform of a corresponding material. The spectral basis may be generated based on an actually measured spectrum or may be calculated based on a density matrix simulation.

The basis set includes a plurality of spectrum bases respectively corresponding to a plurality materials. The basis set includes a plurality of basis fragments obtained by dividing, based on a predetermined criterion, a spectral basis relating to a material of interest which is some or all of the aforementioned materials. Basis fragment means a spectral basis after division. Assume that data on the basis set is stored in the memory 52.

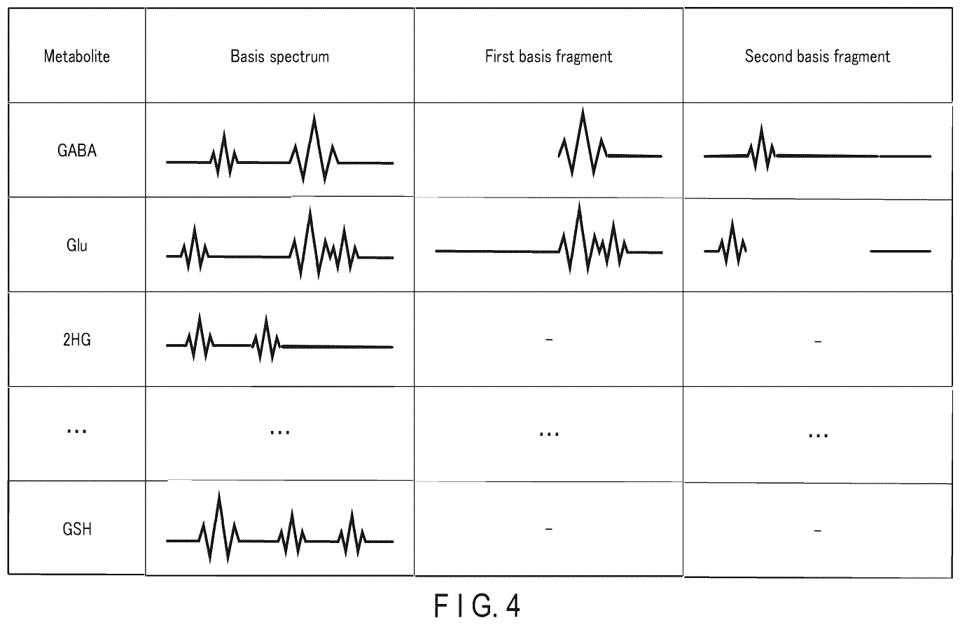

FIG. 4 is a diagram showing an example of a basis set. As shown in FIG. 4, the basis set is a set of spectrum bases for each of the plurality of metabolites targeted for spectrum analysis. The number of metabolites targeted for spectrum analysis is not particularly limited; however, the assumed number is about 10. A spectral basis is registered for each of the metabolites. A plurality of basis fragments are registered for some of the metabolites (hereinafter referred to as a “material of interest”) targeted for spectrum analysis. A material of interest can be directionally set by selecting from among the metabolites targeted for spectrum analysis. As an example, the material of interest can be set to a metabolite a frequency band of whose peak value overlaps that of another metabolite targeted for spectrum analysis. By dividing a spectral basis into a plurality of basis fragments, improvement is expected for the accuracy of regression calculation on a material of interest whose peak value falls within such an overlapping frequency band.

The number of basis fragments with respect to one metabolite may be any number that is equal to or greater than two. As one example, the number of basis fragments in FIG. 4 is two, and a basis fragment belonging to an overlapping frequency band and a basis fragment not belonging to the overlapping frequency band will be referred to as a first basis fragment and a second basis fragment, respectively. Meanwhile, the basis fragment belonging to an overlapping frequency band means a basis fragment whose peak value falls within the overlapping frequency band, whereas the basis fragment not belonging to an overlapping frequency band means a basis fragment whose peak value falls within a frequency band other than the overlapping frequency band. In FIG. 4, the first basis fragment and the second basis fragment are registered for GABA and glucose (Glu), whereas the spectral basis, the first spectral basis, and the second spectral basis are not registered and only the spectral basis is registered for 2HG and GSH.

The division of the spectral basis is performed by the division function 515.

The spectral basis may not be registered for a metabolite for which the basis fragment is registered. That is, it is not necessary that both of the basis fragment and the spectral basis are registered for a metabolite as long as one of them is registered therefor. As a matter of course, both of the basis fragment and the spectral basis may be registered.

Through realization of the calculation function 514, the processing circuitry 51 performs a regression calculation which applies the basis set input through realization of the input function 513 to the acquired spectrum obtained through realization of the obtainment function 512, and outputs a result of spectrum analysis based on the regression calculation. As the result of spectrum analysis, the processing circuitry 51 outputs a material name, a concentration value, a deviation, etc., for each of the materials.

Through realization of the division function 515, the processing circuitry 51 divides a spectral basis relating to a material of interest which is some or all of a plurality of materials, into a plurality of basis fragments based on a predetermined criterion. The plurality of basis fragments are included in the basis set.

Through realization of the display control function 516, the processing circuitry 51 causes a display device such as the display 53 to display various types of information. As an example, the processing circuitry 51 causes the display 53 to display a result of spectrum analysis output through realization of the calculation function 514.

The memory 52 is a storage apparatus such as a hard disk drive (HDD), a solid state drive (SSD), an integrated circuitry storage apparatus, or the like that stores various types of information. The memory 52 may be a drive that reads and writes various types of information from and in a portable storage medium such as a CD-ROM drive, a DVD drive, or a flash memory.

The display 53 displays various types of information under control of the display control function 516. Examples of the display 53 that can be used as appropriate include a CRT display, a liquid crystal display, an organic EL display, an LED display, a plasma display, or any other display known in the art.

The input interface 54 includes an input device that receives various commands from the user. Examples of the input device that can be used include a keyboard, a mouse, various switches, a touch screen, a touch pad, and the like. The input device is not limited to a device with a physical operation component, such as a mouse or a keyboard. For example, examples of the input interface 54 also include electrical signal processing circuitry that receives an electrical signal corresponding to an input operation from an external input device provided separately from the magnetic resonance signal acquisition apparatus 1, and outputs the received electrical signal to various types of circuitry. The input interface 54 may be a speech recognition device that converts audio signals acquired by a microphone into command signals.

The communication interface 55 is an interface connecting the magnetic resonance signal acquisition apparatus 1 with a workstation, a picture archiving and communication system (PACS), a hospital information system (HIS), a radiology information system (RIS), and the like via a local area network (LAN) or the like. The communication interface 55 transmits and receives various types of information to and from the connected workstation, PACS, HIS, and RIS.

Next, division processing of a spectral basis realized through realization of the division function 515 of the processing circuitry 51 will be described. By way of example, the following description will assume the material of interest to be GABA.

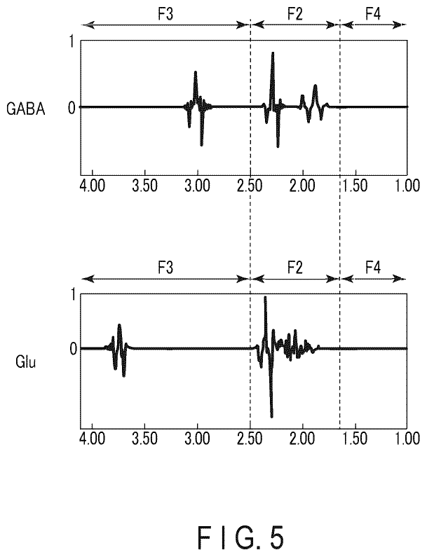

FIG. 5 is a diagram showing examples of a GABA spectrum and a glucose (Glu) spectrum. As shown in FIG. 5, GABA and Glu have peak values within a frequency band F2 between 1.8 and 2.4 ppm. GABA has the peak value within a frequency band around 3.0 ppm in a frequency band F3 of 2.4 ppm or greater. Glu has the peak value within a frequency band around 3.7 to 3.8 ppm in the frequency band F3 of 2.4 ppm or greater. The peak values of GABA and Glu do not fall within a frequency band F4 below 1.8 ppm. Since the peak values of GABA and Glu fall within the frequency band F2 between 1.8 and 2.4 ppm, the local frequency band F2 is set to the overlapping frequency band. Meanwhile, Glu is an example of a metabolite whose peak value falls within the overlapping frequency band F2 within which the peak value of GABA also falls.

In a case of applying the frequency selective pulse, in which the edition frequency band is set, to the overlapping frequency band F2, in the second spectrum of GABA, the peak value appears in a frequency band around 3.0 ppm due to the effect of J-coupling with a partial structure of GABA whose peak value falls within the overlapping frequency band F2. Similarly, in a case of applying the frequency selective pulse including the edition frequency band to the overlapping frequency band F2, in the second spectrum of Glu, the peak value appears in a frequency band around 3.7 to 3.8 ppm due to the effect of J-coupling with a partial structure of Glu whose peak value falls within the overlapping frequency band F2.

In a case of using a basis set including only spectrum bases each having a standard spectrum waveform of a material, the accuracy of regression calculation in editing MRS is often relatively low. One of the reasons for this is that editing MRS uses a spectral basis having a standard waveform of a material regardless of the fact that a spectrum waveform deforms upon application of a frequency selective pulse, thereby causing inconsistency in a spectrum waveform between the spectral basis and the acquired spectrum.

Through realization of the division function 515, the processing circuitry 51 according to the present embodiment divides a spectral basis relating to a material of interest which is some or all of a plurality of materials, into a plurality of basis fragments based on a predetermined criterion (hereinafter referred to as a “division criterion”). As an example, a first division criterion is an overlapping frequency band in which a frequency band to which a material of interest belongs and a frequency band to which another material belongs overlap each other. In such a case, a plurality of basis fragments include a first basis fragment whose peak value falls within the overlapping frequency band and a second basis fragment whose peak value falls within a frequency band other than the overlapping frequency band. The division can be performed using a filter, etc., with respect to an actually measured spectrum or density matrix simulation data. As another method, the division can be performed by switching the initial state in a density matrix simulation.

A division criterion can be set from various points of view. A division criterion (second criterion) from a different point of view is an edition frequency band in an editing MRS pulse sequence. In such a case, a plurality of basis fragments include the first basis fragment whose peak value falls within an edition frequency band and the second basis fragment whose peak value falls within a frequency band other than the edition frequency band. In a case where the edition frequency band is set to the overlapping frequency band, a basis fragment based on the first division criterion and a basis fragment based on the second division criterion are substantially identical. In this example, the number of edition frequency bands is one.

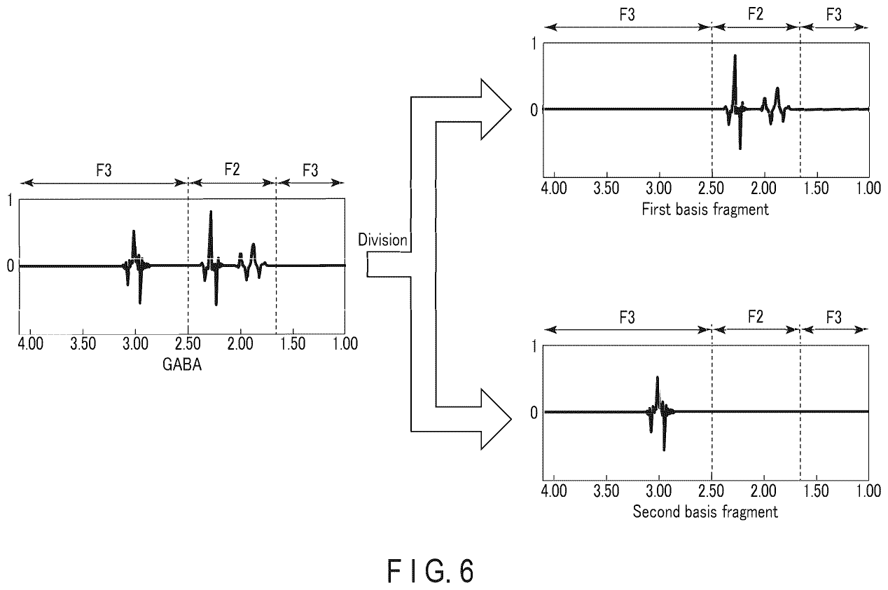

FIG. 6 is a diagram showing an example of division processing of a spectral basis using the second division criterion (the number of edition frequency bands is one). In the example shown in FIG. 6, for GABA, which is a material of interest, a frequency band between 1.6 and 2.5 ppm is set to the edition frequency band F2. In a standard spectral basis of GABA, a peak value falls within each of the edition frequency band F2 and the different frequency band F3. The processing circuitry 51 divides the standard spectral basis of GABA into the first basis fragment corresponding to the edition frequency band F2 and the second basis fragment corresponding to the different frequency band F3. The first basis fragment exhibits a spectrum waveform in which, in a standard spectral basis, a peak value falls within the edition frequency band F2 and does not fall within the different frequency band F3. The second basis fragment exhibits a spectrum waveform in which, in a standard spectral basis, a peak value falls within the different frequency band F3 and does not fall within the edition frequency band F2.

As an example, the processing circuitry 51 can generate the first basis fragment by extracting a spectrum waveform of the edition frequency band F2 in a standard spectral basis and by replacing a spectrum waveform of the different frequency band F3 with a flat waveform of OAU. Similarly, the processing circuitry 51 can generate the second basis fragment by extracting a spectrum waveform of the different frequency band F3 in the standard basis spectrum and by replacing a spectrum waveform of the edition frequency band F2 with a flat waveform of OAU. The processing circuitry 51 may apply a smoothing filter to a boundary between the edition frequency band F2 and the different frequency band F3 in order to prevent a rapid change of a spectrum waveform in the boundary.

In the above embodiment, the number of edition frequency bands is one; however, this is not a limitation. The number of edition frequency bands may be two or more. For example, in a case of two edition frequency bands including a first edition frequency band and a second edition frequency band, the first basis fragments include a basis fragment whose peak value falls within the first edition frequency band and a basis fragment whose peak value falls within the second edition frequency band. The second basis fragment relating to a non-edition frequency band includes a basis fragment whose peak value falls within a different frequency band other than the first edition frequency band and the second edition frequency band.

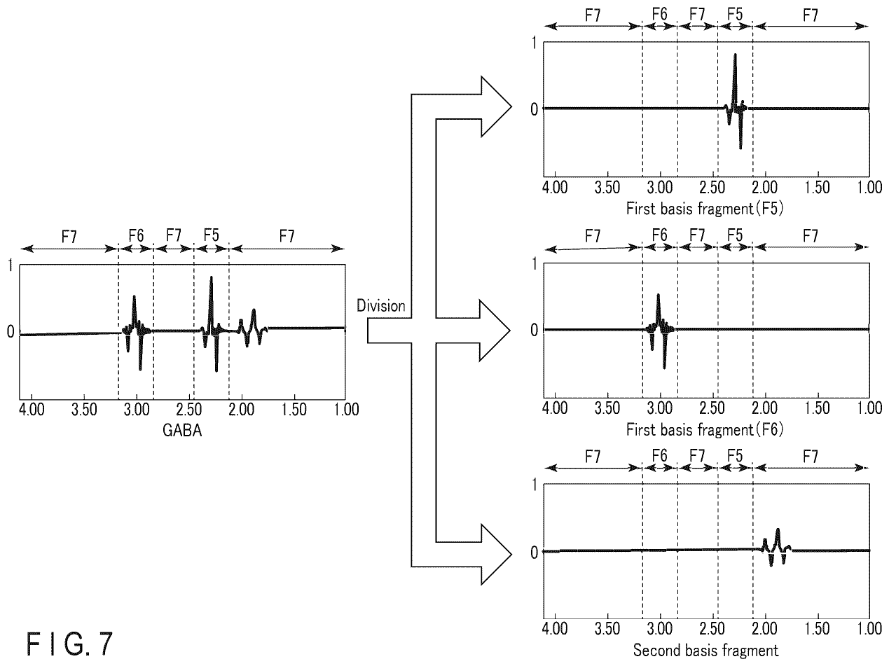

FIG. 7 is a diagram showing an example of division processing of a spectral basis using a second division criterion (the number of edition frequency bands is two). In the example shown in FIG. 7, for GABA, which is a material of interest, a frequency band between 2.1 and 2.4 ppm is set to a first edition frequency band F5 and a frequency band between 2.8 and 3.2 ppm is set to a second edition frequency band F6. In a standard basis spectrum of GABA, a peak value falls within each of the first edition frequency band F5, the second edition frequency band F6, and a different frequency band F7. The processing circuitry 51 divides the standard basis spectrum of GABA into a first basis fragment (F5) corresponding to the edition frequency band F5, a first basis fragment (F6) corresponding to the second edition frequency band F6, and a second basis fragment corresponding to the different frequency band F7. The first basis fragment (F5) exhibits a spectrum waveform in which, in a standard spectral basis, a peak value falls within the edition frequency band F5 and does not fall within the second edition frequency band F6 and the different frequency band F7. The first basis fragment (F6) exhibits a spectrum waveform in which, in a standard spectral basis, a peak value falls within the second edition frequency band F6 and does not fall within the first edition frequency band F5 and the different frequency band F7. The second basis fragment exhibits a spectrum waveform in which, in a standard spectral basis, a peak value falls within the different frequency band F7 and does not fall within the first edition frequency band F5 and the second edition frequency band F6.

As an example, the processing circuitry 51 can generate the first basis fragment (F5) by extracting a spectrum waveform of the first edition frequency band F5 in a standard spectral basis and by replacing a spectrum waveform of each of the second edition frequency band F6 and the different frequency band F7 with a flat waveform of OAU. Similarly, the processing circuitry 51 can generate the first basis fragment (F6) by extracting a spectrum waveform of the second edition frequency band F6 in the standard basis spectrum and by replacing a spectrum waveform of each of the first edition frequency band F5 and the different frequency band F7 with a flat waveform of OAU. Similarly, the processing circuitry 51 can generate the second basis fragment by extracting a spectrum waveform of the different frequency band F7 in the standard basis spectrum and by replacing a spectrum waveform of each of the first edition frequency band F5 and the second edition frequency band F6 with a flat waveform of OAU. The processing circuitry 51 may apply a smoothing filter to a boundary between the first edition frequency band F5 and the different frequency band F7 and a boundary between the second edition frequency band F6 and the different frequency band F7 in order to prevent a rapid change of a spectrum waveform in these boundaries.

A division criterion (third division criterion) from a further different point of view may be provided. The third division criterion is a frequency of a target proton included in a solvent. In such a case, a plurality of basis fragments include a first basis fragment relating to a first frequency band close to the frequency of the target proton included in the solvent, and a second basis fragment relating to a second frequency band further away from the frequency of the target proton than the first frequency band. The following description assumes that the solvent is water and the target proton is a hydrogen atomic nucleus. If target protons are of the same type, their frequency depends on the surrounding environment. Thus, “a frequency of a hydrogen atomic nucleus included in water” will be simply referred to as “a frequency of water”. The frequency of water typically corresponds to 4.65 ppm of an MRS spectrum but can be set to a given frequency value. The following description assumes that the frequency of water is 4.65 ppm.

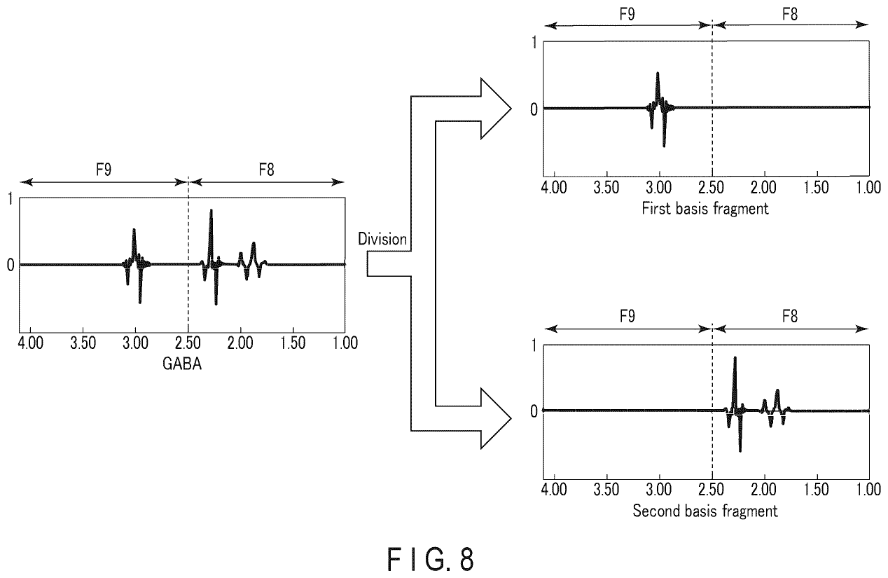

FIG. 8 is a diagram showing an example of division processing of a basis spectrum using the third division criterion. In the example shown in FIG. 8, for GABA, which is a material of interest, a frequency band F9 close to the frequency of water of 4.65 ppm and a frequency band F8 further away from the frequency of water of 4.65 ppm than the frequency band F8 are set with a threshold value 2.5 ppm being a boundary. As an example, the threshold value may be set to a boundary between the edition frequency bands. The processing circuitry 51 divides the standard basis spectrum of GABA into the first basis fragment corresponding to the edition frequency band F9 and the second basis fragment corresponding to the frequency band F8. The first basis fragment exhibits a spectrum waveform in which, in a standard spectral basis, a peak value falls within the frequency band F9 and does not fall within the edition frequency band F8. The second basis fragment exhibits a spectrum waveform in which, in a standard spectral basis, a peak value falls within the frequency band F8 and does not fall within the frequency band F9. As with the first and second division criteria, a basis fragment can also be generated using the third division criterion.

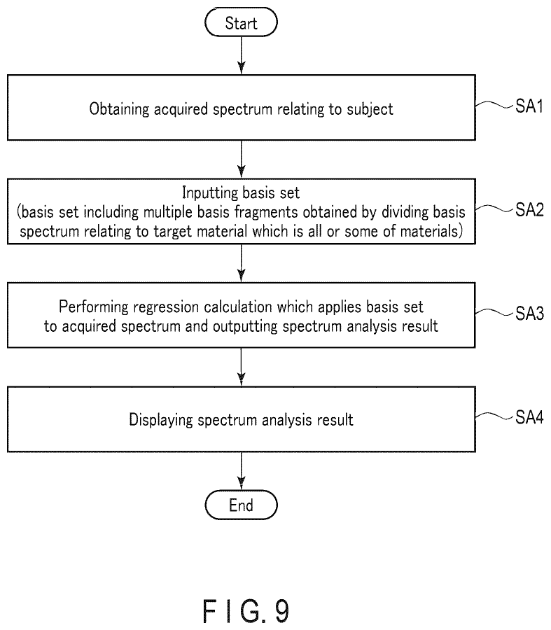

Next, spectrum analysis processing by a spectrum analysis apparatus 50 will be described with reference to FIG. 9. FIG. 9 is a diagram showing an example of a processing procedure of the spectrum analysis processing by the spectrum analysis apparatus 50. It is assumed that the processing circuitry 51 has performed signal acquisition by editing MRS on the subject S and an acquired spectrum relating to the subject S has been acquired before the spectrum analysis processing is started.

As shown in FIG. 9, through realization of the obtainment function 512, the processing circuitry 51 acquires an acquired k-space spectrum relating to the subject S (step SA1). The acquired spectrum may be any one of a first spectrum acquired through a basic sequence without a frequency selective pulse, a second spectrum acquired through a sequence with a frequency selective pulse, and/or a subtraction spectrum between the first spectrum and the second spectrum.

After step SA1, the processing circuitry 51 inputs a basis set (step SA2) through realization of the input function 513. In step SA2, the processing circuitry 51 reads the basis set stored in the memory 52, and writes the read basis set in a working memory for a regression calculation. The basis set includes a plurality of spectrum bases respectively corresponding to a plurality of metabolites targeted for spectrum analysis. A part or an entirety of the plurality of spectrum bases includes a first basis fragment and a second basis fragment divided in accordance with a division criterion. The division criterion may be any of the first, second and third division criteria described above; however, the following assumes the second division criterion and the number of edition frequency bands is one.

After step SA2, through realization of the calculation function 514, the processing circuitry 51 performs a regression calculation which applies the basis set input in step SA2 on the acquired spectrum acquired in step SA1, and outputs a result of spectrum analysis (step SA3). Specifically, with respect to the acquired spectrum, the processing circuitry 51 performs a regression calculation (fitting) on each basis spectrum and/or each basis fragment constituting each basis set, obtains a result of the regression calculation indicative of the degree of deformation of the basis spectrum and/or basis fragment, and estimates a concentration value of a metabolite corresponding to the basis spectrum and/or the basis fragment in accordance with the result of the regression calculation. More specifically, the processing circuitry 51 obtains a result of a regression calculation on the second basis fragment with respect to a material of interest, and obtains a result of a regression calculation on the basis spectrum with respect to a metabolite targeted for another spectrum analysis. The processing circuitry 51 estimates a result of spectrum analysis of a material of interest based on a result of a regression calculation relating to the material of interest, and estimates a result of spectrum analysis of a metabolite targeted for another spectrum analysis, based on a result of a regression calculation relating to the metabolite. A regression calculation using a basis spectrum is similar to that of prior art. Thus, a regression calculation using a basis fragment will be described. A plurality of types of regression calculation methods using a basis fragment are available. In the following, a few regression calculation methods will be described.

First Regression Calculation Method: As described above, the first basis fragment has a peak value within the overlapping frequency band or the edition frequency band, and the second basis fragment has a peak value within the frequency band other than the overlapping frequency band or the edition frequency band. Thus, it is estimated that a result of a regression calculation of the first basis fragment is lower in accuracy than a result of a regulation calculation of the second basis fragment. Thus, the processing circuitry 51 performs a regression calculation which applies the first basis fragment and the second basis fragment to the acquired spectrum and removes a result of a regression result relating to the first basis fragment, thereby calculating a result of spectrum analysis relating to a material of interest based on a result of a regression calculation relating to the second basis fragment. The processing circuitry 51 outputs a result of spectrum analysis relating to the material of interest.

Second Regression Calculation Method: A result of spectrum analysis may be output in consideration of a result of a regression calculation of the first basis fragment. Thus, the processing circuitry 51 performs a regression calculation which applies the first basis fragment and the second basis fragment to the acquired spectrum, thereby calculating a result of a spectrum analysis relating to a material of interest based on a regression calculation relating to the first basis fragment and a regression calculation relating to the second basis fragment. The processing circuitry 51 outputs a result of spectrum analysis relating to a material of interest. As an example, the processing circuitry 51 may calculate a result of spectrum analysis relating to a material of interest based a regression calculation relating to the first basis fragment or a regression calculation relating to the second basis fragment, whichever is higher in reliability. The reliability may be assigned in advance to each of the first basis fragment and the second basis fragment, or may be calculated with reference to a result of a regression calculation of each of the first basis fragment and the second basis fragment. The processing circuitry 51 may weight-add the result of regression calculation relating to the first basis fragment and the result of regression calculation relating to the second basis fragment in accordance with the reliability, and calculate a result of spectrum analysis based on the weight-added results of regression calculations.

Third Regression Calculation Method: A regression calculation relating to the first basis fragment may not be performed. The processing circuitry 51 performs a regression calculation which applies the second basis fragment to the acquired spectrum, and does not perform a regression calculation which applies the first basis fragment to the acquired spectrum, thereby calculating a result of spectrum analysis relating to a material of interest based on a regression calculation relating to the second basis fragment. The processing circuitry 51 outputs a result of spectrum analysis relating to a material of interest.

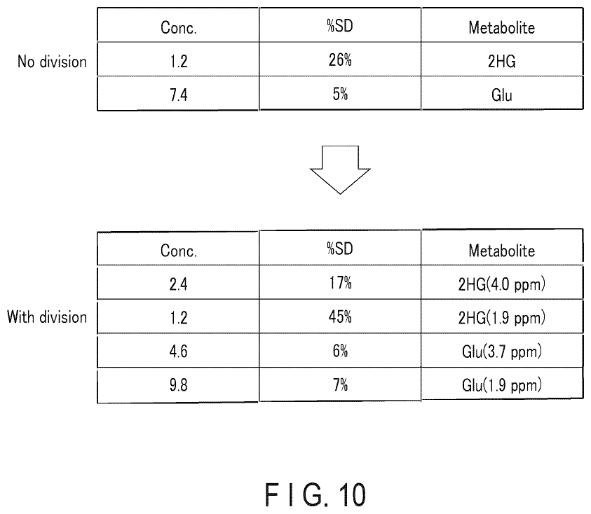

FIG. 10 is a diagram showing an example of a result of spectrum analysis in a case of a basis spectrum being not divided, and a result of spectrum analysis in a case of the basis spectrum being divided. In FIG. 10, the concentration “Conc.”, a deviation “% SD”, and a metabolite name “Metabolite” are examples of a result of spectrum analysis. A result of spectrum analysis without division is based on a regression calculation utilizing a basis spectrum, and a result of spectrum analysis with division is based on a regression calculation utilizing a basis fragment. FIG. 10 shows results of spectrum analysis of 2HG and Glu as examples of a metabolite. It is assumed that 2HG exhibits a peak value around 1.9 ppm and 4.0 ppm, and Glu exhibits a peak value around 1.9 ppm and 3.7 ppm. 2HG and Glu exhibit peak values around 1.9 ppm. Thus, it is assumed that the edition frequency band is set to a narrow frequency band including 1.9 ppm.

“2HG (4.0 ppm)” indicates that a metabolite name is 2HG, and a result of spectrum analysis has been calculated utilizing the second basis fragment whose peak value falls within a narrow frequency band of 4.0 ppm. “2HG (1.9 ppm)” indicates that a metabolite name is 2HG, and a result of spectrum analysis has been calculated utilizing the first basis fragment whose peak value falls within an edition frequency band of 1.9 ppm. Similarly, “Glue (3.7 ppm)” indicates that a metabolite name is Glue, and a result of spectrum analysis has been calculated utilizing the second basis fragment whose peak value falls within a narrow frequency band of 3.7 ppm. “Glu (1.9 ppm)” indicates that a metabolite name is Glu, and a result of spectrum analysis has been calculated utilizing the first basis fragment whose peak value falls within an edition frequency band of 1.9 ppm.

As shown in FIG. 10, a comparison of the result of spectrum analysis with division with the result of spectrum analysis without division shows that the result of spectrum analysis utilizing the second basis fragment is better than the result of analysis result utilizing the first basis fragment. One of the reasons for this is that the result of regression calculation of the first basis fragment is low in the accuracy of regression calculation due to overlapping between peak values of 2HG and Glu but the result of regression calculation of the second basis fragment is high in the accuracy of regression calculation because there is no overlapping between peak values of 2HG and Glu. According to the present embodiment, the influence of overlapping between peak values of different metabolites can be reduced by dividing the basis spectrum into the first basis fragment and the second basis fragment.

After step SA3, through realization of the display control function 516, the processing circuitry 51 causes the display 53 to display the result of spectrum analysis output in step SA3 (step SA4). As the result of spectrum analysis, a result of spectrum analysis in table form shown in FIG. 10 may be displayed or a graph such as a bar graph in which results of spectrum analysis of metabolites targeted for spectrum analysis or materials of interest may be arranged for each item of spectrum analysis (such as a concentration, a deviation, etc.).

The spectrum analysis processing by the spectrum analysis apparatus 50 is thereby completed.

The spectrum analysis processing shown in FIG. 9 is an example. Various types of processing can be deleted, added, and/or altered in the present embodiment. As an example, the order of the step (SA1) of obtaining an acquired spectrum and the step (SA2) of inputting a basis set may be reverse. Furthermore, the step (SA4) of displaying a result of spectrum analysis is not essential. For example, the result of spectrum analysis may be stored in the memory 52 or may be transferred to another computer via the communication interface 55.

Next, determination processing of a basis set by the spectrum analysis apparatus 50 will be described. There are various methods of determining a basis set, and an example of the methods will be described below. As an example, a basis set is generated based on an acquired spectrum of a phantom including a plurality of materials each having a known concentration. The phantom is an example of the subject S. Through the calculation function 514, the processing circuitry 51 performs a regression calculation for each of a plurality of basis sets each having a different pattern of division into a plurality of basis fragments, and selects a basis set to use from among the plurality of basis sets. By this, a basis set to use is determined. Such spectrum analysis processing as shown in FIG. 9 is performed using the basis set thus determined.

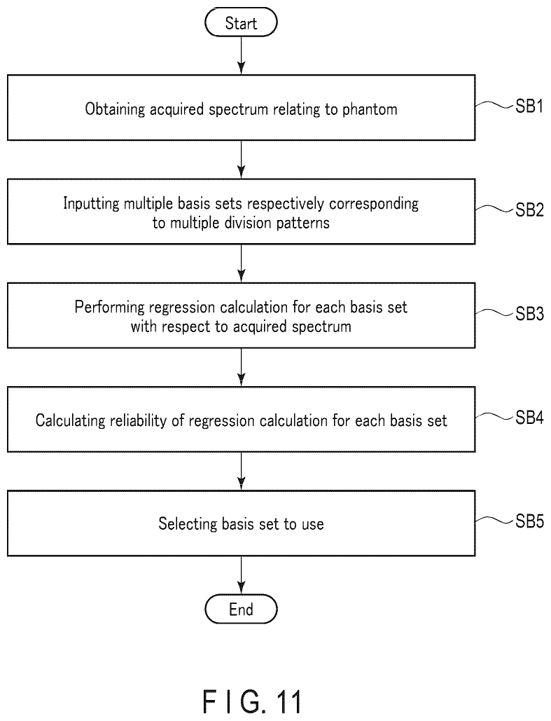

FIG. 11 is a diagram showing an example of a processing procedure of determination processing of a basis set by the spectrum analysis apparatus 50. It is assumed that the processing circuitry 51 has performed signal acquisition by editing MRS on a phantom serving as the subject S and an acquired spectrum relating to the phantom has been acquired before the spectrum analysis processing is started. Meanwhile, the phantom is provided with a plurality of metabolites each having a known concentration.

As shown in FIG. 11, through realization of the obtainment function 512, the processing circuitry 51 obtains an acquired spectrum relating to the phantom (step SB1). The acquired spectrum may be any one of a first spectrum acquired through a basic sequence without a frequency selective pulse, a second spectrum acquired through a sequence with a frequency selective pulse, and/or a subtraction spectrum between the first spectrum and the second spectrum.

After step SB1, the processing circuitry 51 inputs a plurality of basis sets respectively corresponding to a plurality of division patterns through realization of the input function 513 (step SB2). The plurality of basis sets are generated in advance by the processing circuitry 51 through realization of the division function 515. A plurality of basis sets each include a plurality of spectrum bases and/or basis fragments respectively corresponding to a plurality of common metabolites targeted for spectrum analysis. The division pattern is defined by a type of material of interest in which division of a basis spectrum is performed, the number of basis fragments per material, and a combination of overlapping frequency bands, etc.

After step SB2, through realization of the calculation function 514, the processing circuitry 51 performs a regression calculation for each of the basis sets input in step SB2, on the acquired spectrum obtained in step SB1 (step SB3). The regression calculation method is similar to the above method.

After step SB3, the processing circuitry 51 calculates the reliability of regression calculation for each of the basis sets through realization of the calculation function 514 (step SB4). Various types of reliability can be used as a reliability. As an example, a deviation between an estimated concentration value which is a result of a regression calculation and a correct value can be used as a reliability. In such a case, a function to define a reliability such that the reliability increases as the deviation decreases is designed. As a correct value, an actual concentration value of a metabolite included in a phantom is used.

In step SB4, through realization of the calculation function 514, the processing circuitry 51 selects a basis set to use (step SB5). In step SB5, the processing circuitry 51 selects a basis set to use based on a reliability for each basis set calculated in step SB4. Typically, the processing circuitry 51 may select a basis set having the highest reliability among a plurality of basis sets as a basis set to use. The basis set to use is stored in the memory 52.

The determination processing of a basis set by the spectrum analysis apparatus 50 is thus completed.

Meanwhile, the determination processing of a basis set shown in FIG. 11 is one example. Various types of processing can be deleted, added, and/or altered in the present embodiment. As an example, the order of the step (SB1) of obtaining an acquired spectrum and the step (SB2) of inputting a basis set may be reversed. In a case of selecting a basis set without using a reliability, the step of calculating a reliability (SB4) is unnecessary. For example, a user who has confirmed a result of a regression calculation for each basis set may select a basis set to use from among a plurality of basis sets.

A spectrum analysis apparatus according to an embodiment includes the processing circuitry 51. The processing circuitry 51 obtains an acquired spectrum of an MRS pulse sequence with respect to the subject S. The processing circuitry 51 inputs a basis set including a plurality of spectrum bases respectively corresponding to a plurality of materials targeted for spectrum analysis. The basis set includes a plurality of basis fragments obtained by dividing, based on a predetermined criterion, a basis spectrum relating to a material of interest which is some or all of the aforementioned materials. The processing circuitry 51 performs a regression calculation which applies the basis set to the acquired spectrum and outputs a result of spectrum analysis based on the regression calculation.

According to the above configuration, by dividing the basis spectrum into a plurality of basis fragments, a regression calculation can be performed while avoiding a frequency band in which peak values of a plurality of metabolites overlap each other. Therefore, according to the present embodiment, deterioration in the result of spectrum analysis due to overlapping between peak values of a plurality of metabolites can be reduced.

According to at least one embodiment described above, the accuracy in analysis can be improved in a spectrum analysis method using a regression calculation according to MR spectroscopy.

The term “processor” used in the above explanation indicates, for example, a circuit, such as a CPU, a GPU, or an application specific integrated circuit (ASIC), and a programmable logic device (for example, a simple programmable logic device (SPLD), a complex programmable logic device (CPLD), and a field programmable gate array (FPGA)). A processor realizes its functions by reading and executing a program stored in storage circuitry. Instead of storing a program on storage circuitry, a program may be directly integrated into circuitry of a processor. In this case, a processor reads and executes a program integrated into circuitry, thereby realizing its functions. On the other hand, if the processor is for example an ASIC, the function is directly implemented in a circuit of the processor as a logic circuit, instead of storing a program in a storage circuit. Each processor of the present embodiment is not limited to a configuration as a single circuit; a plurality of independent circuits may be combined into one processor to realize the function of the processor. Furthermore, a plurality of structural elements in FIG. 1 may be integrated as one processor to realize the respective functions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A spectrum analysis apparatus comprising processing circuitry configured to:
obtain an acquired spectrum through an MRS pulse sequence with respect to a subject;
input a basis set including a plurality of spectrum bases respectively corresponding to a plurality of materials, the basis set including a plurality of basis fragments obtained by dividing, based on a predetermined criterion, a basis spectrum relating to a material of interest which is all or some of the materials; and
perform a regression calculation which applies the basis set to the acquired spectrum and output a result of spectrum analysis based on the regression calculation.

2. The spectrum analysis apparatus according to claim 1, wherein
the criterion is an overlapping frequency band in which a frequency band to which a peak value of the material of interest belongs and a frequency band to which a peak value of a different material belongs overlap each other, and
the plurality of basis fragments include a first basis fragment whose peak value falls within the overlapping frequency band and a second basis fragment whose peak value falls within a frequency band other than the overlapping frequency band.

3. The spectrum analysis apparatus according to claim 1, wherein
the criterion is an edition frequency band in an editing MRS pulse sequence which is the MRS pulse sequence, and
the plurality of basis fragments include a first basis fragment whose peak value falls within the edition frequency band and a second basis fragment whose peak value falls within a frequency band other than the edition frequency band.

4. The spectrum analysis apparatus according to claim 3, wherein the edition frequency band is one frequency band.

5. The spectrum analysis apparatus according to claim 3, wherein
the edition frequency band is two frequency bands,
the first base fragment includes a base fragment whose peak value falls within a first edition frequency band of the two frequency bands, and a base fragment whose peak value falls within a second edition frequency band, and
the second base fragment includes a base fragment whose peak value falls within a different frequency band other than the first edition frequency band and the second edition frequency band.

6. The spectrum analysis apparatus according to claim 1, wherein
the criterion is a frequency of a target proton included in a solvent, and
the plurality of basis fragments include a first basis fragment relating to a first frequency band close to the frequency of the target proton, and a second basis fragment relating to a second frequency band further away from the frequency of the target proton than the first frequency band.

7. The spectrum analysis apparatus according to claim 2, wherein the processing circuitry performs a regression calculation which applies the first base fragment and the second base fragment to the acquired spectrum, removes a result of a regression calculation relating to the first base fragment, and outputs the result of spectrum analysis relating to the material of interest based on a result of a regression calculation relating to the second base fragment.

8. The spectrum analysis apparatus according to claim 2, wherein the processing circuitry performs a regression calculation which applies the first base fragment and the second base fragment to the acquired spectrum, and outputs the result of spectrum analysis relating to the material of interest based on a regression calculation relating to the first base fragment and a regression calculation relating to the second base fragment.

9. The spectrum analysis apparatus according to claim 8, wherein the processing circuitry calculates the result of spectrum analysis relating to the material of interest based on a regression calculation relating to the first basis fragment or a regression calculation relating to the second basis fragment, whichever is higher in reliability.

10. The spectrum analysis apparatus according to claim 2, wherein the processing circuitry performs a regression calculation which applies the second basis fragment to the acquired spectrum, does not perform a regression calculation which applies the first basis fragment to the acquired spectrum, and outputs the result of spectrum analysis relating to the material of interest based on a regression calculation relating to the second basis fragment.

11. The spectrum analysis apparatus according to claim 1, wherein
the subject is a phantom including the plurality of materials each having a known concentration, and
the processing circuitry performs the regression calculation for each of a plurality of basis sets each having a different pattern of division into the plurality of basis fragments, and selects a basis set for use from among the plurality of basis sets.

12. The spectrum analysis apparatus according to claim 1, wherein the processing circuitry divides a basis spectrum relating to a material of interest which is some or all of the plurality of materials into the plurality of basis fragments based on the predetermined criterion.

13. The spectrum analysis apparatus according to claim 1, wherein as the result of spectrum analysis, the processing circuitry outputs a material name, a concentration, and/or a deviation for each of the plurality of materials.

14. The spectrum analysis apparatus according to claim 1, wherein the processing circuitry causes a display device to display the result of spectrum analysis.

15. The spectrum analysis apparatus according to claim 3, wherein the processing circuitry performs a regression calculation which applies the first base fragment and the second base fragment to the acquired spectrum, removes a result of a regression calculation relating to the first base fragment, and outputs the result of spectrum analysis relating to the material of interest based on a result of a regression calculation relating to the second base fragment.

16. The spectrum analysis apparatus according to claim 3, wherein the processing circuitry performs a regression calculation which applies the first base fragment and the second base fragment to the acquired spectrum, and outputs the result of spectrum analysis relating to the material of interest based on a regression calculation relating to the first base fragment and a regression calculation relating to the second base fragment.

17. The spectrum analysis apparatus according to claim 16, wherein the processing circuitry calculates the result of spectrum analysis relating to the material of interest based on a regression calculation relating to the first basis fragment or a regression calculation relating to the second basis fragment, whichever is higher in reliability.

18. The spectrum analysis apparatus according to claim 3, wherein the processing circuitry performs a regression calculation which applies the second basis fragment to the acquired spectrum, does not perform a regression calculation which applies the first basis fragment to the acquired spectrum, and outputs the result of spectrum analysis relating to the material of interest based on a regression calculation relating to the second basis fragment.

19. The spectrum analysis apparatus according to claim 6, wherein the processing circuitry performs a regression calculation which applies the first base fragment and the second base fragment to the acquired spectrum, removes a result of a regression calculation relating to the first base fragment, and outputs the result of spectrum analysis relating to the material of interest based on a result of a regression calculation relating to the second base fragment.

20. The spectrum analysis apparatus according to claim 6, wherein the processing circuitry performs a regression calculation which applies the first base fragment and the second base fragment to the acquired spectrum, and outputs the result of spectrum analysis relating to the material of interest based on a regression calculation relating to the first base fragment and a regression calculation relating to the second base fragment.

21. The spectrum analysis apparatus according to claim 20, wherein the processing circuitry calculates the result of spectrum analysis relating to the material of interest based on a regression calculation relating to the first basis fragment or a regression calculation relating to the second basis fragment, whichever is higher in reliability.

22. The spectrum analysis apparatus according to claim 6, wherein the processing circuitry performs a regression calculation which applies the second basis fragment to the acquired spectrum, does not perform a regression calculation which applies the first basis fragment to the acquired spectrum, and outputs the result of spectrum analysis relating to the material of interest based on a regression calculation relating to the second basis fragment.

23. A spectrum analysis method comprising:
obtaining an acquired spectrum of an MRS pulse sequence with respect to a subject;
inputting a basis set including a plurality of spectrum bases respectively corresponding to a plurality of materials, the basis set including a plurality of basis fragments obtained by dividing, based on a predetermined criterion, a basis spectrum relating to a material of interest which is some or all of the materials; and
performing a regression calculation which applies the basis set to the acquired spectrum and outputting a result of spectrum analysis based on the regression calculation.

24. A non-transitory computer readable medium including computer executable instructions, wherein the instructions, when executed by a processor, cause the processor to perform operations comprising:
obtaining an acquired spectrum of an MRS pulse sequence with respect to a subject;
inputting a basis set including a plurality of spectrum bases respectively corresponding to a plurality of materials, the basis set including a plurality of basis fragments obtained by dividing, based on a predetermined criterion, a basis spectrum relating to a material of interest which is some or all of the materials; and
performing a regression calculation which applies the basis set to the acquired spectrum and outputting a result of spectrum analysis based on the regression calculation.
